(19) United States
(12) Patent Application Publication
(10) Pub. No.: US 2006/0087013 A1
(43) Pub. Date: Apr. 27, 2006

(54) Stacked multiple integrated circuit die package assembly

(75) Inventor: Yung-Ching Hsieh, Hsinchu (TW)

Correspondence Address: STEPHEN B. ACKERMAN, 28 DAVIS AVENUE, POUGHKEEPSIE, NY, 12603, US

(73) Assignee: Etron Technology, Inc.

(21) Appl. No.: 10/970,785

(22) Filed: Oct. 21, 2004

(51) Int. Cl. H01L 23/02

(52) U.S. Cl. 257/678

(57) ABSTRACT

An electronic package assembly is formed with a plurality of integrated circuit dies stacked in layers. At least one first die is placed on a substrate. Each subsequent layer of the stack contains at least one die. Each die on each layer has a size and shape such that, when placed on the dies on a lower layer, it is offset from the edges of the dies on the lower layer to allow affixing of wirebonds to input/output pads of the dies on the lower layer. Each die on each layer with more than one die has input/output pads placed on two sides of the die. Each die on an upper layer is placed orthogonally to each die of a lower each layer such that wirebonds are affixed without interference.

### BACKGROUND OF THE INVENTION

1. Field of the Invention

This invention relates generally to electronic package assemblies and methods. More particularly, this invention relates to three-dimensional electronic package assemblies containing multiple stacked integrated circuit dies.

2. Description of Related Art

Stacked, or three-dimensional (3D), multiple die packaging methodologies are provide a low-cost, high-volume solution that help system designers reduce the size, weight, and power consumption for small, portable, and wireless consumer devices such as cellular telephone or personal digital assistants. The stacked multiple die packages are commonly referred to as “chip scaled packaging” (CSP). When these packages are used to implement a complete functional system, they are referred to as a system-in-package (SIP). Generally, the SIP includes a computational processor (i.e. a video processor, a digital signal processor, wireless communication controller), at least one random access memory (RAM) integrated circuit, and a memory controller integrated circuit.

The stacked multiple die packages usually include two, three and four wire-bonded dies in a stack. Stacks of five, six and more dies are presently in development for low-volume production. The integrated circuit dies are typically stacked in a pyramid where the dies are of decreasing size for each level of the stack. In the case where the dies are the same sized, the dies are stacked with and intervening interposer to allow spacing for looping of the wire bonding.

To minimize the thickness of the stacked multiple die packages to the current thickness of 1.2 mm, the wafer containing the die to be packaged must be thinned. In the current technology, the wafers are thinned to a thickness of 100 μm. As the package thickness is decreased to approximately 0.8 mm for future applications, the wafer thickness will become as low as approximately 50 μm.

Refer now to FIG. 1 for a description of a pyramidal multiple die stacked package of the prior art. A first integrated circuit die 5 is provided and generally attached to a substrate (not shown) such as printed circuit card (chip-on-card), or a plastic or ceramic chip carrier (pin grid array or ball grid array). The input/output pads 10 are placed at the peripheral edges of the die for attachment to the substrate. The second integrated circuit die 15 is adhered to the first integrated circuit die 5 with an adhesive such as an epoxy. The second integrated circuit die 15 is designed so that the maximum dimensions of the die allows placement of the second integrated circuit die 15 to be offset from the edges of the first integrated circuit die 5. The offset distance allows positioning of the input/output pads 10 thus allowing a wirebonder to connect wirebonds to these input/output pads 10. The second integrated circuit die's 15 input/output pads 20 are placed near the peripheral edges of the second integrated circuit die 15.

This structure is repeated for the third integrated circuit die 25 and fourth integrated circuit die 35 with the die adhered successively to the lower integrated circuit die. The dimensions of the third integrated circuit die 25 and fourth integrated circuit die 35 being determined as with the second integrated circuit die 15 by the placement of the input/output pads 20 and 30 to permit the positioning of the wirebonds. The input/output pads 40 of the fourth integrated circuit die 35 are place at the peripheral edges of the fourth integrated circuit die 35.

Communications between the first, second, third, and fourth integrated circuit die 5, 15, 25, and 35 are through the wirebonds 40, . . . , 70. The wirebonds 45 connect the fourth integrated circuit die 35 to the first integrated circuit die 5. The wirebonds 50 connect the third integrated circuit die 25 to the first integrated circuit die 5. The wirebonds 50 connect the second integrated circuit die 15 to the first integrated circuit die 5. The wirebonds 60 connect the fourth integrated circuit die 35 to the second integrated circuit die 15. The wirebonds 65 connect the third integrated circuit die 25 to the second integrated circuit die 15. The wirebonds 70 connect the fourth integrated circuit die 35 to the third integrated circuit die 25. The wirebonds 40, . . . , 70 are shown as a singular wirebonds for simplicity of illustration. However, these wirebonds 40, . . . , 70 represent multiple bonds between the first, second, third, and fourth integrated circuit die 5, 15, 25, and 35 for the required interconnections.

The structure of the pyramidal multiple die stacked package of the prior art, as shown, has the die stacked on the top of another larger die and the smaller die is placed in the center of the larger die. The input/output bonding pads are placed on all four edges of the die. The drawback of this kind of stacking method is that the size of each die for each successive layer is reduced. The reduction in the die size makes the connection of the input/output bonding pads across several dies more difficult.

“Stackable Packages with Integrated Components,” Ostmann, et al. Proceedings 2003 5th Conference (EPTC 2003) on Electronics Packaging Technology, December 2003, pp: 9-23 describes a technology for the integration of thin chips into built-up layers of organic substrates, and an improved and simplified concept for the realization of stackable chip packages is presented.

“Development of High Density Memory IC Package by Stacking IC Chips,” Nakanishi et al, Proceedings, 45th Electronic Components and Technology Conference, May 1995, pp: 634-640 describes a stacked chip package in which two memory chips are stacked with no increase in package thickness The chips are mounted on the top and bottom sides of a die pad. A polyimide film coats the chip surface to prevent cracking of the passivation.

“Stacked Chip-To-Chip Interconnections Using Wafer Bonding Technology with Dielectric Bonding Glues,” Lu, et al. Proceedings of the IEEE 2001 International Interconnect Technology Conference, 2001, pp: 219-221 describes a specific approach to three-dimensional (3D) interconnects that incorporates wafer alignment and wafer bonding of two 200-mm silicon wafers, along with subsequent processing steps. Dielectrics are used as the bonding glue layer to provide a monolithic 3D interconnect process, which is fully compatible with back-end-of-the-line processing.

“A 3-D Stacked Chip Packaging Solution for Miniaturized Massively Parallel Processing,” Lea, et al. IEEE Transactions on Advanced Packaging, Volume: 22, August 1999, pp: 424-432, details the development and evaluation of a three-dimensional (3-D) interconnect and packaging technology for massively parallel processor (MPP) implementation is reported. A highly compact 3-D chip-stack integrates five MPP chips in a single package.

U.S. Patent Application 20030042621 (Chen, et al.) illustrates a microelectronic assembly that includes a multiple integrated circuit chip stack attached to a substrate such as a ball grid array. The electroplated gold bumps or electroless nickel/gold bumps are formed on all of the integrated circuit chips and wire stitch bonds are formed on the electroplated gold bumps or electroless nickel/gold bumps thereby connecting the integrated circuit chips to each other or to an underlying ball grid array.

U.S. Pat. No. 6,724,074 (Song, et al.) describes a stacked semiconductor chip package and lead frame. The lead frame has two lead groups respectively corresponding to two integrated circuit chips. The lead frame also has multiple external connection terminals for electrically interconnecting the two integrated circuit chips to an external device. Each of the two integrated circuit chips has its own common and independent electrode pads, and each of the two lead groups has its own common and independent leads. The common leads and the common electrode pads are for address and control signals to and from the two integrated circuit chips. The independent leads and the independent electrode pads are for data input and output to and from the two integrated circuit chips. The common leads of the first lead group and the common leads of the second lead group are commonly interconnected to be connected to an identical external connection terminal of the plurality of external connection terminals. The independent leads of the first lead group and the independent leads of the second lead group are connected to different external connection terminals. The two integrated circuit chips are disposed symmetrically with respect to the common leads and face each other with their backsides.

U.S. Pat. No. 6,714,418 (Frankowsky, et al.) teaches an electronic component that has multiple chips that are stacked one above the other and contact-connected to one another. To form this component, a first planar chip arrangement is provided with the functional chips spaced apart from one another in a grid and with a filling material in the spaces between the chips to form an insulating holding frame that fixes the chips. The frame has chip-dedicated contact-connecting elements that serve for the electrical contact-connection to another chip of another chip arrangement; and each chip has dedicated electrically conductive strips. At least one additional planar chip arrangement is formed by the same method as the first planar chip arrangement and is then stacked on the first planar chip arrangement so that the two chip arrangements lie one above the other and the respective contact-connecting elements of the two chip arrangements are connected to one another for electrical chip-to-chip contact-connection. Subsequently, each of the components, which comprise a stack of chips, is separated from the assembled stack of chip arrangements.

U.S. Pat. No. 6,699,730 (Kim, et al.) teaches a method for a stacked microelectronic assembly that includes providing a flexible substrate with a plurality of attachment sites, test contacts and conductive terminals, and including a wiring layer with leads extending to the attachment sites. The method includes assembling a plurality of integrated circuit chips to the attachment sites and electrically interconnecting the integrated circuit chips and the leads. The flexible substrate is then folded to stack some of the integrated circuit chips in substantially vertical alignment with one another to provide a stacked assembly with the conductive terminals exposed at the bottom end and the top end of the stack.

U.S. Pat. No. 6,686,656 (Koh, et al.) describes a vertically integrated chip scale package (CSP) assembly comprising two or more single chip package subassemblies having an upper level CSP subassembly superimposed directly above a lower level CSP subassembly. The lower-most CSP subassembly in the vertical stack contains an array of solder balls for interconnection to a printed wiring board. The vertical electrical connection between the upper and lower level package subassemblies is accomplished by using wire bonding from perimeter wire bonding pads located on an upper level substrate extension to matching perimeter wire bonding pads located on a lower level substrate extension that is longer in length than the upper level substrate extension. The stacked package subassemblies are bonded together by using a thin adhesive material, and the perimeter wire bonds are encapsulated for protection.

U.S. Pat. No. 6,686,654 (Farrar, et al.) illustrates an electronic package comprised of multiple chip stacks attached together to form a single, compact electronic module. The module is hermetically sealed in an enclosure. The enclosure contains a pressurized, thermally conductive fluid, which is utilized for cooling the enclosed chip stack.

U.S. Pat. No. 6,650,008 (Tsai, et al.) details a stacked semiconductor packaging device. The device has a substrate with a first chip with a back surface faced towards the substrate and an active surface with wire bonds connected to the substrate. A second chip similarly has a back surface attached to the substrate and an active surface with wire bonds connected to the substrate. The active surface of the second chip is faced towards the active surface of said first chip and is stacked atop the first chip so as to expose all of the bonding pads. The face-to-face arrangement of the first chip and the second chip reduces the whole packing height.

U.S. Pat. No. 6,630,744 (Tsuda) describes a small multichip module with a mother chip and a stack chip placed upon the mother chip. The mother chip includes a first bonding pad located in a circuit area. A bonding pad of the stack chip is wire-bonded with the bonding pad of the mother chip.

U.S. Pat. No. 6,583,502 (Lee, et al.) details a method and apparatus for assembling semiconductor die-carrying interposer substrates in a stacked configuration. Each interposer substrate bears at least one die mounted by its active surface to a surface of the substrate and wire bonded to terminals on the opposing substrate surface through an opening in the substrate. Two interposer substrates are placed together with die carrying sides outward and electrically connected with conductive elements extending transversely between the interposers to form an interposer assembly. The interposer assembly bears conductive elements extending transversely from one of the interposer substrates for connection to a carrier substrate.

U.S. Pat. No. 6,555,919 (Tsai, et al.) teaches a low profile stack semiconductor package with at least two chips, that has centrally-situated bond pads is stacked on a substrate that is formed with a through opening. A first chip is mounted on the substrate, with bond pads being exposed to the opening. A second chip mounted on the first chip is formed with a peripherally-situated cushion member, whereby bonding wires are adapted to extend from bond pads of the second chip in a direction parallel to the chip, and reach the cushion member beyond which the bonding wires turn downwardly to be directed toward the substrate. The bonding wires are free of forming wire loops since they extend above the second chip. The bonding wires are firmly held in position to be free from contact or short circuit with the second chip.

U.S. Pat. No. 6,476,506 (O'Connor, et al.) illustrates a packaged semiconductor with multiple rows of bond pads. A semiconductor die has three rows or more of bond pads with minimum pitch. The die is mounted on a package substrate with three or more rows of bond fingers and/or conductive rings. The bond pads on the outermost part of the die (nearest the perimeter of the die) are connected by a relatively lower height wire achieved by reverse stitching to the innermost ring(s) or row (farthest from the perimeter of the package substrate) of bond fingers. The innermost row of bond pads is connected by a relatively higher height wire achieved by ball bond to wedge bond to the outermost row of the bond fingers. The intermediate row of bond pads is connected by relatively intermediate height wire by ball bond to wedge bond to the intermediate row of bond fingers. The varying height wire allows for tightly packed bond pads. The structure for bonding the bond pads allows stacked die to communicate with each other and with externals circuitry.

U.S. Pat. No. 6,407,456 (Ball) describes a multi-chip device utilizing a flip chip and wire bond assembly. The device has an upper die and a lower die. The lower die is a flip-chip, which is connected to a conductor-carrying substrate or a lead frame. The upper die is attached back-to-back to the lower die with a layer of adhesive applied over the back side of the lower die. Bond wires or TAB leads are attached between bond pads on the upper die and corresponding conductive trace or lead ends on the substrate. The upper die may be smaller than the lower die such that a small discrete component such as a resistor, capacitor, or the like can be attached to the adhesive not covered by the upper die. Bond wires can be attached between the upper die and the component, as well as between the component and the substrate. One or more additional die may be stacked on the upper die and electrically connected to the substrate. Furthermore, multiple lower dies can be arranged on the substrate to support upper dies bridged between the lower dies.

U.S. Pat. No. 5,579,207 (Hayden, et al.) illustrates a three-dimensional integrated circuit stacking package. Multiple integrated circuit chips are packaged in a stack of chips in which a number of individual chip layers are physically and electrically interconnected and are peripherally sealed to one another to form hermetically sealed packages with input/output pads on the surface of the upper and lower layers. Each chip layer comprises a chip carrier substrate having a chip cavity on a bottom side and having a plurality of electrically conductive vias extending completely around the chip cavity. Each substrate is formed with a peripheral sealing strip on its top and bottom sides. Mounted on its top side is a chip that has connecting pads wire bonded to exposed traces of a pattern of traces that are formed on the top side of the substrate and on intermediate layers of this multi-layer substrate. The traces interconnect with the vias that extend completely through the substrate. Each via is provided at the top and bottom sides of the substrate with a via connecting pad, with the via pads on top and bottom sides all arranged in identical patterns. Solder on the via pads and on the sealing strips is reflowed to effect a completely sealed package and to interconnect vias in each layer with vias in each other layer.

U.S. Pat. No. 5,422,435 (Takiar, et al.) describes a stacked multi-chip module. The circuit assembly has a substrate on which at least one integrated circuit chip is attached. A second chip is then placed on the integrated circuit chip attached forming a stack. Connections from the second chip and the first chip are made with wire bonding. FIG. 10 illustrates a multi-chip module with four integrated circuit die mounted on the principal mounting surface of a carrier. Each integrated circuit dies has planar opposing surfaces. The integrated circuit dies are arranged in two separate stacks. The integrated circuit dies are connected by wire bond connections.

U.S. Pat. No. 5,313,096 (Eide) illustrates an integrated circuit chip package having chip attached to and wire bonded within an overlying substrate. The integrated circuit chip package includes a chip with an upper active surface bonded to the lower surface of a substrate. Terminals on the active surface are wire bonded within the outer periphery of the chip by bonding wires extending through apertures in a lower layer of the substrate to bonding pads on an upper surface of the lower substrate layer. Metallized strips couple the bonding pads to conductive pads at the outer edges of the lower substrate layer. The substrate includes an upper layer having apertures which are, after wire bonding, filled with epoxy which is cured and then ground flush with the upper surface of the upper substrate layer.

U.S. Pat. No. 5,025,306 (Johnson, et al.) teaches a three dimensional package having at least one semiconductor chip with input/output conductive pads along its periphery. This includes a dielectric carrier over at least a portion of the chip and a plurality of conductors mounted on the carrier between the chip and the dielectric carrier. The plurality of conductors are mounted within the periphery of the chip with one end connected to the conductive pads and with the other end of the plurality of conductors exiting from the same side of the chip. The plurality of conductors exiting from the same side are electrically coupled to an interconnect substrate.

U.S. Reissued Pat. RE36,613 (Ball) describes a multiple stacked die device that contains up to four dies and does not exceed the height of single die packages. Close-tolerance stacking is made possible by a low-loop-profile wire-bonding operation and thin-adhesive layer between the stacked dies.

### SUMMARY OF THE INVENTION

An object of this invention is to provide a stacked multiple integrated circuit die package assembly in which layers of the stack of integrated circuit die contain more than one integrated circuit die.

Another object of this invention is to provide an electronic system in a package with stacked multiple integrated circuit die in which layers of the stack of integrated circuit die contain more than one integrated circuit die such as a random memory integrated circuit die.

To accomplish at least one of these objects, an electronic package assembly is formed with a plurality of integrated circuit dies stacked in layers. At least one first integrated circuit die of the plurality of integrated circuit dies is placed on a substrate such as a printed circuit card, a plastic die carrier, an integrated circuit module lead frame, and a ceramic die carrier. Each layer of the stack contains at least one integrated circuit die.

Each integrated circuit die on each layer of integrated circuit dies has a size and shape such that, when placed on the integrated circuit dies of a lower layer, each integrated circuit die is offset from edges of the integrated circuit dies of the lower layer. The offset from the edges allows affixing of wirebonds to input/output pads of the integrated circuit dies on the lower layer. Each integrated circuit die on each layer with more than one integrated circuit die has input/output pads placed on two sides of the integrated circuit die such that each integrated circuit die on an upper layer are placed orthogonally to each integrated circuit die on the lower layer such that wirebonds affixed to each integrated circuit die does not interfere.

A system in package assembly is formed where at least one integrated circuit dies is a computational processor; and at least one integrated circuit dies is a random access memory; and at least one integrated circuit dies is a memory controller providing address, timing, and control signals for the integrated circuit die that is the random access memory. The integrated circuit dies that are random access memory has a rectangular shape. The input/output pads of the integrated circuit dies that are random access memory are placed at two sides of the integrated circuit dies that are random access memory. If the integrated circuit die of the upper layer is also a random access memory, the integrated circuit die of the upper layer that is a random access memory is placed orthogonally to the integrated circuit die that is a random access memory. The integrated circuit die that is a memory controller is interconnected with the integrated circuit die that is a random access memory by wirebond connections between layers of the stack of integrated circuit die.

### BRIEF DESCRIPTION OF THE DRAWINGS

FIG. 1 is an isometric view of an electronic package assembly of a pyramidal stack of integrated circuit dies of the prior art.

FIG. 2 is an isometric view of an electronic package assembly of a stack of integrated circuit dies of this invention.

FIG. 3 is a block diagram of a system in a package assembly of this invention.

FIG. 4 is a flow chart for the process for forming an electronic package assembly of a stack of integrated circuit die of this invention.

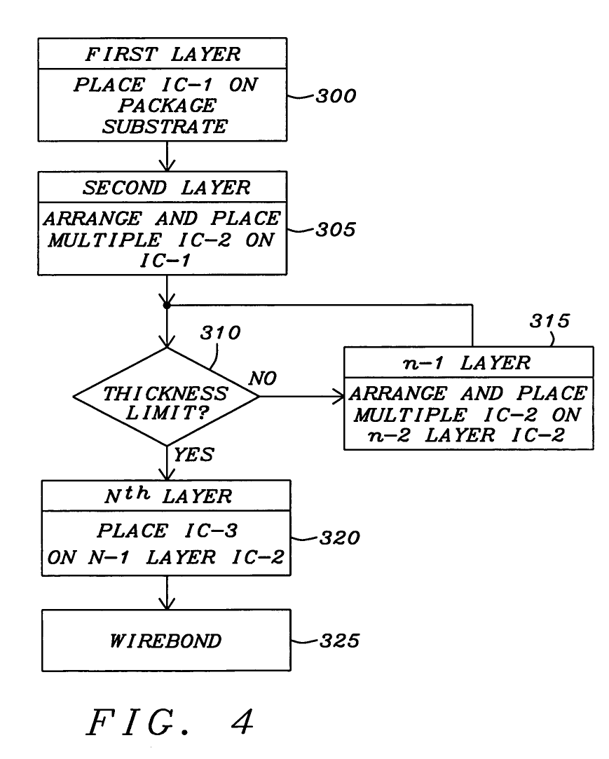

### DETAILED DESCRIPTION OF THE INVENTION

The electronic package assembly provides multiple integrated circuits dies arranged in a stack. A first layer of the stack is adhered to a substrate such as a printed circuit card, a plastic die carrier, and a ceramic die carrier. Certain layers of the stack contain two or more integrated circuit dies. The sizes and shapes of the integrated circuit dies are selected such that, when the integrated circuit dies are mounted to integrated circuit dies of a lower layer, they are offset from the edges of the integrated circuit dies on the lower layer. The offset distance is chosen such that wirebonds can be attached to the integrated circuit dies of the lower layer.

The integrated circuit dies on layers with two or more integrated circuit dies have input/output pads placed on two edges of the dies. When two adjacent layers have two or more integrated circuit dies, the integrated circuit dies of each layer are placed orthogonally to permit placement of wirebonds on the integrated circuit dies of each layer such they do not interfere.

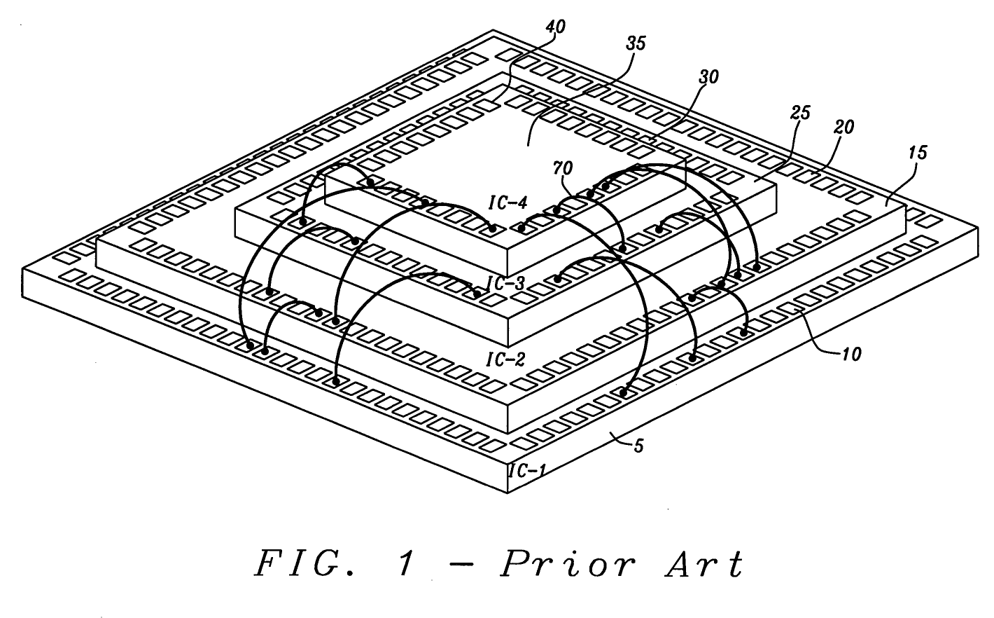

Refer now to FIG. 1 for a detailed description of an embodiment of the electronic package assembly of this invention. A first integrated circuit die 105 is provided and attached to a substrate (not shown) such as printed circuit card (chip-on-card), or a plastic or ceramic chip carrier (pin grid array or ball grid array). A first pair of second integrated circuit dies 115a and 115b is placed on the surface of the first integrated circuit die 105 and secured in place with an adhesive such as an epoxy or polyimide in a technique known in the art.

The first pair of second integrated circuit dies 115a and 115b are rectangular in shape and have a size that when placed on the first integrated circuit die 105 they are offset from the four edges of the first integrated circuit die 105. The distance of the offset is determined by the amount of space required by a wirebonder used in attaching wirebonds 135, 145, and 150 to the input/output pads 110 of the first integrated circuit die 105.

The input/output pads 120a and 120b of the second integrated circuit dies 115a and 115b are placed at two edges of the second integrated circuit dies 115a and 115b. In the case shown, the input/output pads 120a and 120b are placed at the periphery of the short sides of the second integrated circuit dies 115a and 115b.

A second pair of the second integrated circuit dies 115c and 115d are oriented orthogonally to the first pair of second integrated circuit dies 115a and 115b. The second pair of the second integrated circuit dies 115c and 115d are offset from the edges of the first pair of second integrated circuit dies 115a and 115b such that the wirebonder can place wirebonds 135, 140, 150, and 155, on the input/output pads 120a and 120b of the first pair of second integrated circuit dies 115a and 115b. By placing the second pair of the second integrated circuit dies 115c and 115d orthogonally to the first pair of second integrated circuit dies 115a and 115b, the wirebonds 140 of the first pair of second integrated circuit dies 115a and 115b do not interfere with the wirebonds 150 and 155 of the second pair of the second integrated circuit dies 115c and 115d.

A third integrated circuit die 125 is placed on the second pair of the second integrated circuit dies 115c and 115d and adhered with an adhesive as described above to the second pair of the second integrated circuit dies 115c and 115d. The third integrated circuit die 125 is also sized and shaped such that when placed on the second pair of the second integrated circuit dies 115c and 115d, it is offset from the input/output pads 120c and 120d of the second pair of the second integrated circuit dies 115c and 115d such that the wirebonder has sufficient space to place the wirebonds 150 and 155 on the input/output pads 120c and 120d.

The third integrated circuit die 125 has bondpads 130 placed at the periphery of the die. The wirebonds 140, 145, and 155 are adhered to the bondpads 130. The wirebonds 135 provide the communication of command and data signals between the first integrated circuit die 105 and the first pair of second integrated circuit dies 115a and 115b. The wirebonds 145 provide the communication of command and data signals between the first integrated circuit die 105 and the third integrated circuit die 125. The wirebonds 150 provide the communication of command and data signals between the first integrated circuit die 105 and the second pair of the second integrated circuit dies 115c and 115d. The wirebonds 140 provide the communication of command and data signals between the third integrated circuit die 125 and the first pair of second integrated circuit dies 115a and 115b. The wirebonds 155 provide the communication of command and data signals between the third integrated circuit die 125 and the second pair of the second integrated circuit dies 115c and 115d.

While the second integrated circuit dies 115a, 115b, 115c, and 115d are shown as rectangular with their input output pads 120a, 120b, 120c, and 120d placed at the short edges of the second integrated circuit dies 115a and 115b, it is in keeping with the intent that the chips maybe square and the input output pads 120a, 120b, 120c, and 120d maybe placed on adjacent sides of the second integrated circuit dies 115a, 115b, 115c, and 115d such that four of the integrated circuit dies maybe placed on a layer. Alternately, the short edges of the second integrated circuit dies 115a, 115b, 115c, and 115d maybe scaled such that three of the integrated circuit dies maybe place on each layer. A key provision of this invention is that the integrated circuit dies are oriented to allow the placement of the bondwires of the layers such that they do not interfere and the input/output pads are placed on the edges of the integrated circuit die to allow the orientation of the integrated circuit dies of the various layers to be altered to prevent the interference of the bondwires.

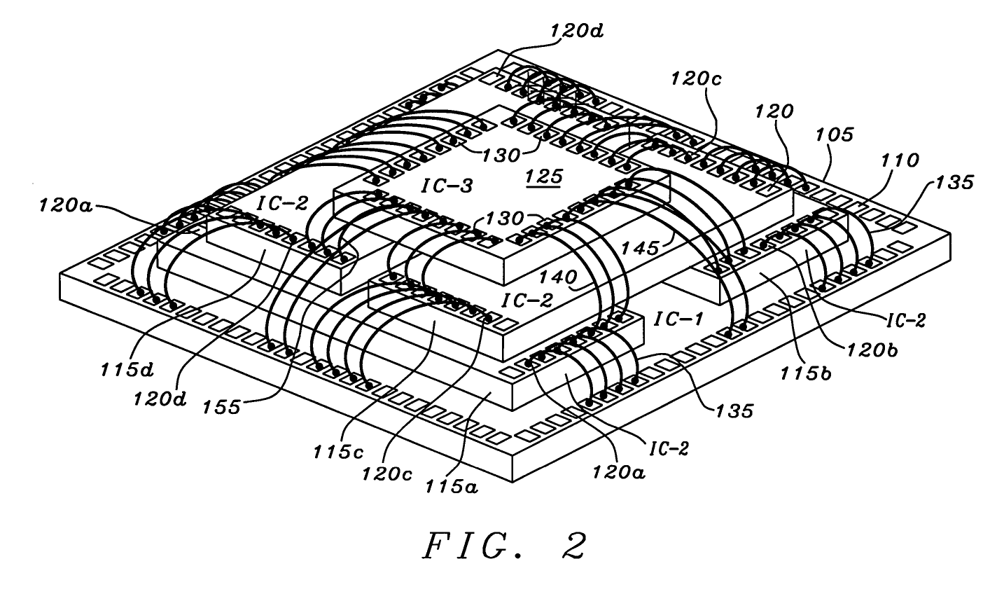

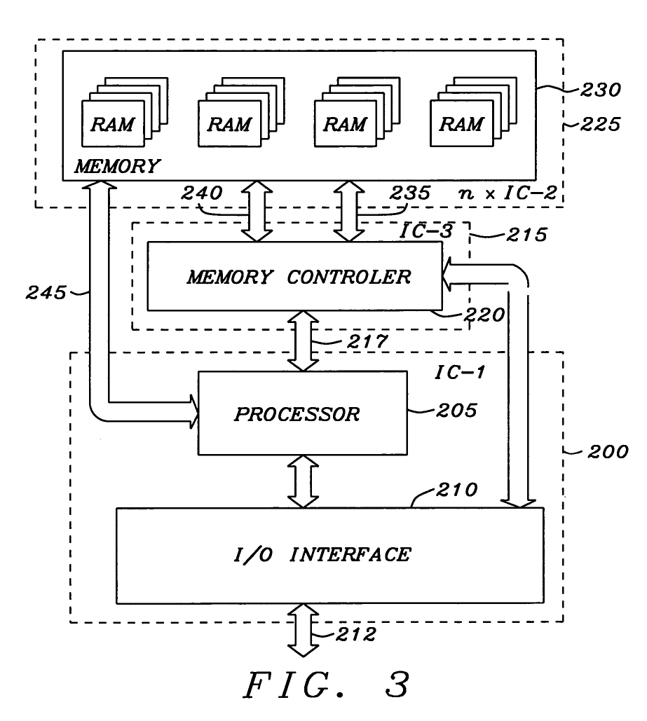

The stacked multiple integrated circuit die electronic assembly of this invention as described in FIG. 2 may be an SIP (system in package) as described above. Referring to FIG. 3, the SIP includes at least one computational processor integrated circuit die 200. The computational processor integrated circuit die 200 has a computational processor 205 and a input/output interface 210. The computational processor maybe a digital signal processor for application such as a cellular telephone, a computer processor for such applications as a personal digital assistant, or a video processor for such applications as a liquid crystal display or monitor for a digital television. The processor 205 has a data interface 245 that is in communication with multiple second integrated circuit die on to which the memory 230 is integrated. The further processor 205 has a data and control interface 217 that is in communication with a memory controller 220 that is integrated into a third integrated circuit die. The memory controller 220 further has an address and control bus 235 and a data bus 240 in communication with each of the memories 230 of the second integrated circuit dies 225. The number (n) of second integrated circuit dies is determined by the size of memory required to service the processor 205.

The input/output interface within the computational processor integrated circuit die 200 communicates with external circuitry of the SIP electronic assembly through the input/output bus 212 that is generally wirebonds between the substrate and the first integrated circuit die 105 of FIG. 2. The wirebonds 135, 140, 145, 150, 155 of FIG. 2 provide communication between the processor integrated circuit die 200, second integrated circuit dies 225, and the third integrated circuit die 215 and the data and control interface 217, the address and control bus 235, the data bus 240, and the data interface 245.

The structure of placing multiple integrated circuit dies on a layer of a stacked multiple integrated circuit dies electronic assembly of this invention permits usage of multiple computational processors with appropriate communication with the memory. Further, the rectangular shapes of the memory integrated circuit dies permits the placement of differing types of random access memory such as dynamic random access memory, static random access memory, read only memory, and flash memory within the same SIP assembly.

The method for forming an electronic package assembly of this invention as described in FIG. 3 begins by providing multiple integrated circuit dies IC1 110, IC2 120a, 120b, 120c, 120d, and IC3 125 of FIG. 2. One of a first type integrated circuit die (IC1 125) is arranged, placed, and adhered (Box 300) to a substrate, such as a printed circuit card, an integrated circuit module lead frame, a plastic die carrier and a ceramic die carrier. One of the multiple dies of a second type of integrated circuit die (IC2 120a, 120b, 120c, and 120d) is arranged, placed, and adhered (Box 305) in a stack on the one first type of integrated circuit (IC 125). The thickness of the electronic package assembly is checked (Box 310) and if the thickness limit is not exceeded, the remaining dies of the second type of integrated circuit dies (120b, 120c, and 120d) for the current layer (n−1) are arranged, placed, and adhered (Box 315) to the lower layer (n−2) of the electronic package assembly.

When the thickness limit for the number of dies (n−1) is met or the number of dies of the second type of integrated circuit die (IC2 120a, 120b, 120c, and 120d) are arranged, placed, and adhered (Box 315), the third type of integrated circuit die (IC3 125) is placed and adhered (Box 320) to the next lower layer (n−1) thus forming a stack of the multiple integrated circuit dies IC1 110, IC2 120a, 120b, 120c, 120d, and IC3 125 of FIG. 2 with at least one integrated circuit die on each layer of the stack.

Each integrated circuit die on each layer of integrated circuit dies has a size and shape such that, when placed on the integrated circuit dies of a lower layer, each integrated circuit die is offset from edges of the integrated circuit dies on the lower layer to allow affixing of wirebonds to input/output pads of the integrated circuit dies of the lower layer. Each integrated circuit die on each layer with more than one integrated circuit die has input/output pads placed on two sides of the integrated circuit die. Each integrated circuit die on an upper layer are placed orthogonally to each integrated circuit die on a lower layer such that wirebonds affixed to each integrated circuit die do not interfere.

As described above the first type of integrated circuit dies IC1 110 is a computational processor. The second types of integrated circuit die (IC2 120a, 120b, 120c, and 120d) are random access memory. The random access memory has a rectangular shape. The input/output pads of the random access memory integrated circuit dies are placed at two short sides of the random access memory such that, if the integrated circuit die of the upper layer is also a random access memory, the random access memory of the upper layer is placed orthogonally to the random access memory integrated circuit dies on the lower layer. The third type of integrated circuit die (IC3 125) is a memory controller providing address, timing, and control signals for the random access memory. The multiple integrated circuit dies IC1 110, IC2 120a, 120b, 120c, 120d, and IC3 125 are interconnected by wirebond connections between layers of the stack of multiple integrated circuit dies IC1 110, IC2 120a, 120b, 120c, 120d, and IC3 125.

While this invention has been particularly shown and described with reference to the preferred embodiments thereof, it will be understood by those skilled in the art that various changes in form and details may be made without departing from the spirit and scope of the invention.

The invention claimed is:

1. An electronic package assembly comprising:
a plurality of integrated circuit dies stacked in layers with at least on first integrated circuit die of the plurality of integrated circuit dies placed on a substrate, each layer containing at least one integrated circuit die,
wherein each integrated circuit die on each layer of integrated circuit dies has a size and shape such that, when placed on the integrated circuit dies of a lower layer, each of said integrated circuit die is offset from edges of said integrated circuit dies on said lower layer to allow affixing of wirebonds to input/output pads of the integrated circuit dies on said lower layer, and
wherein each integrated circuit die on each layer with more than one integrated circuit die has input/output pads placed on two sides such that each integrated circuit die on an upper layer are placed orthogonally to each integrated circuit die on a lower each layer such that wirebonds affixed to each integrated circuit die do not interfere.

2. The electronic package assembly of claim 1 wherein said substrate is selected from a group of substrates consisting of a printed circuit card, a plastic die carrier, an integrated circuit module lead frame, and a ceramic die carrier.

3. The electronic package assembly of claim 1 wherein at least one integrated circuit dies is a computational processor.

4. The electronic package assembly of claim 1 wherein at least one of said integrated circuit dies is a random access memory.

5. The electronic package assembly of claim 4 wherein said integrated circuit dies that are the random access memory has a rectangular shape and the input/output pads of said integrated circuit dies that are the random access memory are placed at two sides of said integrated circuit dies that are the random access memory such that, if said integrated circuit dies of the upper layer is also random access memory, said integrated circuit dies on said upper layer that are random access memory is placed orthogonally to said integrated circuit dies on the lower that are the random access memory.

6. The electronic package assembly of claim 4 wherein at least one of said integrated circuit dies is a memory controller that provides address, timing, and control signals for said integrated circuit dies that are the random access memory.

7. The electronic package assembly of claim 6 wherein said integrated circuit die that is a memory controller is interconnected with said integrated circuit dies that are the random access memory by wirebond connections between layers of said stack of integrated circuit die.

8. An electronic package assembly comprising:
at least one first integrated circuit dies with input/output pads at the periphery of four edges of said integrated circuit die; and
a plurality of second integrated circuit dies with a rectangular shape and with input/output pads at the periphery of two edges of said integrated circuit die;
wherein said first and second integrated circuit dies are stacked with a first layer of said stack adhered to a substrate;
wherein said first and second integrated circuit dies have dimensions such that when adhered to a first lower layer the first and second integrated circuit dies are offset from the four edges of the first and second integrated circuit dies on said first lower layer by a distance defined by the input/output pads of the first and second integrated circuit dies on said first lower layer; and
wherein said layers of said first and second integrated circuit dies and said substrate are interconnected with wirebonds.

9. The electronic package assembly of claim 8 wherein said substrate is selected from a group of substrates consisting of a printed circuit card, a plastic die carrier, an integrated circuit module lead frame, and a ceramic die carrier.

10. The electronic package assembly of claim 8 wherein at least one of said first integrated circuit dies is a computational processor.

11. The electronic package assembly of claim 8 wherein one layer containing a first grouping of said second integrated circuit s placed upon a second lower layer with a second grouping of said second integrated circuit dies, said first grouping of said second integrated circuit dies are placed orthogonally to said second grouping of said integrated circuit dies.

12. The electronic package assembly of claim 11 wherein at least one of said second integrated circuit dies is a random access memory.

13. The electronic package assembly of claim 12 wherein at least one of said first integrated circuit dies is a memory controller that provides address, timing, and control signals for said second integrated circuit dies that are the random access memory.

14. The electronic package assembly of claim 13 wherein said first integrated circuit die that is a memory controller is interconnected with said second integrated circuit dies that is a random access memory by wirebond connections between layers of said stack of integrated circuit die.

15. A system integrated package comprising:
at least one computational process controller, each computational process controller formed on a first integrated circuit die with input/output pads at the periphery of four sides of said integrated circuit die;
at least one memory control circuit, each memory control circuit formed on a second integrated circuit die with input/output pads at the periphery of four sides of said integrated circuit die; and
a plurality of random access memory integrated circuits, each random access memory integrated circuits formed on a third integrated circuit die with a rectangular shape and with input/output pads at the periphery of two sides of said integrated circuit die;
wherein said first, second, and third integrated circuit dies are stacked with a first layer of said stack adhered to a substrate;
wherein said first, second, and third integrated circuit dies have dimensions such that when adhered to a first lower layer the first, second, and third integrated circuit dies are placed edges of the first, second, and third integrated circuit dies of said first lower layer defined by the input/output pads of the first, second, and third integrated circuit die of said first lower layer; and
wherein said layers of said first, second, and third integrated circuit dies and said substrate are interconnected with wirebonds.

16. The system integrated package of claim 8 wherein said substrate is selected from a group of substrates consisting of a printed circuit card, a plastic die carrier, an integrated circuit module lead frame, and a ceramic die carrier.

17. The system integrated package of claim 15 wherein one layer containing a first grouping of said third integrated circuit dies is placed upon a second lower layer with a third grouping of said third integrated circuit dies, said first grouping of said third integrated circuit dies are placed orthogonally to said second grouping of said integrated circuit dies.

18. The system integrated package of claim 15 wherein said memory controller that provides address, timing, and control signals for said random access memory.

19. The system integrated package of claim 15 wherein said second integrated circuit die that is a memory controller is interconnected with said third integrated circuit dies that are the random access memory by wirebond connections between layers of said stack of integrated circuit dies.

20. A method for forming an electronic package assembly comprising the steps of:
providing a plurality of integrated circuit dies;
adhering at least one first integrated circuit die of the plurality of integrated circuit dies placed on a substrate; and
forming a stack said plurality of integrated circuit dies with at least one integrated circuit die on each layer of said stack;
wherein each integrated circuit die on each layer of integrated circuit dies has a size and shape such that, when placed on the integrated circuit dies of a lower layer, each of said integrated circuit die is offset from edges of said integrated circuit dies on said lower layer to allow affixing of wirebonds to input/output pads of the integrated circuit dies on said lower layer, and
wherein each integrated circuit die on each layer with more than one integrated circuit die has input/output pads placed on two sides such that each integrated circuit die on an upper layer is placed orthogonally to each integrated circuit die of a lower layer such that wirebonds affixed to each integrated circuit die do not interfere.

21. The method for forming the electronic package assembly of claim 20 wherein said substrate is selected from a group of substrates consisting of a printed circuit card, an integrated circuit module lead frame, a plastic die carrier, and a ceramic die carrier.

22. The method for forming the electronic package assembly of claim 20 wherein at least one integrated circuit dies is a computational processor.

23. The method for forming the electronic package assembly of claim 20 wherein at least one of said integrated circuit dies is a random access memory.

24. The method for forming the electronic package assembly of claim 23 wherein said integrated circuit dies that are the random access memory has a rectangular shape and the input/output pads of said integrated circuit dies that are the random access memory are placed at two sides of said integrated circuit dies that are the random access memory such that, if said integrated circuit die of the upper layer is also random access memory, said integrated circuit dies on said upper layer that are random access memory is placed orthogonally to said integrated circuit dies of the lower layer that are the random access memory.

25. The electronic package assembly of claim 23 wherein at least one of said integrated circuit die is a memory controller that provides address, timing, and control signals for said integrated circuit dies that are the random access memory.

26. The electronic package assembly of claim 25 wherein said integrated circuit die that is a memory controller is interconnected with said integrated circuit dies that are the random access memory by wirebond connections between layers of said stack of integrated circuit die.

27. An apparatus for forming an electronic package assembly comprising:
means for providing a plurality of integrated circuit dies;
means for adhering at least one first integrated circuit die of the plurality of integrated circuit dies placed on a substrate; and
means for forming a stack said plurality of integrated circuit dies with at least one integrated circuit die on each layer of said stack;
wherein each integrated circuit die on each layer of integrated circuit dies has a size and shape such that, when placed on the integrated circuit dies of a lower layer, each integrated circuit die is offset from edges of said integrated circuit dies on said lower layer to allow affixing of wirebonds to input/output pads of the integrated circuit dies on said lower layer, and
wherein each integrated circuit die on each layer with more than one integrated circuit die has input/output pads placed on two sides such that each integrated circuit die on an upper layer is placed orthogonally to each integrated circuit die of a lower layer such that wirebonds affixed to each integrated circuit die do not interfere.

28. The apparatus for forming the electronic package assembly of claim 27 wherein said substrate is selected from a group of substrates consisting of a printed circuit card, an integrated circuit module lead frame, a plastic die carrier, and a ceramic die carrier.

29. The apparatus for forming the electronic package assembly of claim 27 wherein at least one integrated circuit dies is a computational processor.

30. The apparatus for forming the electronic package assembly of claim 27 wherein at least one of said integrated circuit dies is a random access memory.

31. The apparatus for forming the electronic package assembly of claim 30 wherein said integrated circuit dies that are the random access memory has a rectangular shape and the input/output pads of said integrated circuit dies that are the random access memory are placed at two sides of said integrated circuit dies that are the random access memory such that, if said integrated circuit die of the upper layer is also random access memory, said integrated circuit dies on said upper layer that are random access memory is placed orthogonally to said integrated circuit dies on the lower layer that are the random access memory.

32. The apparatus for forming the electronic package assembly of claim 30 wherein at least one of said integrated circuit die is a memory controller that provides address, timing, and control signals for said integrated circuit dies that are the random access memory.

33. The apparatus for forming the electronic package assembly of claim 32 wherein said integrated circuit die that is a memory controller is interconnected with said integrated circuit dies that are the random access memory by wirebond connections between layers of said stack of integrated circuit die.
